(19) United States
(12) Patent Application Publication
(10) Pub. No.: US 2002/0055263 A1
(43) Pub. Date: May 9, 2002

(54) Oxide film etching method

(76) Inventors: Yoshiki Igarashi, Nirasaki-shi (JP); Vaidya Nathan Balasubramaniam, Beverly, MA (US); Tomoki Suemasa, Santa Clara, CA (US); Koichiro Inazawa, Nirasaki-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/956,803

(22) Filed: Sep. 21, 2001

(30) Foreign Application Priority Data
Sep. 21, 2000 (JP) 2000-287259

(51) Int. Cl. H01L 21/302; H01L 21/461

(52) U.S. Cl. 438/710

(57) ABSTRACT

The present invention provides an oxide film etching method performed by using an etching apparatus in which an oxide film formed on a target object to be processed is etched by utilizing a plasma generated within the process chamber by application of a high frequency power. The etching gas introduced into the process chamber in the etching step contains a C₄F₆ gas and an O₂ gas, and the ratio C₄F₆/O₂ of the C₄F₆ gas to the O₂ gas falls within a range of 0.7 and 1.5 so as to increase the etching selectivity of the oxide film relative to a resist film.

### CROSS-REFERENCE TO RELATED APPLICATIONS

This application is based upon and claims the benefit of priority from the prior Japanese Patent Application No. 2000-287259, filed Sep. 21, 2000, the entire contents of which are incorporated herein by reference.

### BACKGROUND OF THE INVENTION

1. Field of the Invention

The present invention relates to an oxide film etching method for etching an oxide film formed on a target object to be processed such as a semiconductor wafer.

2. Description of the Related Art

In recent years, further miniaturization and further improvement in the degree of integration are required in the semiconductor device. In this connection, it is required to form a finer pattern in the circuit element or an interconnection. Such being the situation, in forming a pattern by the dry etching in the lithography process, it is necessary to form a finer mask pattern with a higher resolution by coating a semiconductor wafer with a thin resist film forming the etching mask.

On the other hand, a plasma generated under an etching gas atmosphere containing mainly a C₄F₈ gas or a C₅F₈ gas is used in etching a silicon oxide film. However, the etching selectivity of the silicon oxide film relative to the resist, i.e., the ratio of the etching rate of the silicon oxide film to the etching rate of the resist film, is low in the plasma etching performed under the plasma generated by using these gases. As a result, the resist film is also etched in a considerably large amount in, particularly, the shoulder portion of the contact hole.

To reiterate, the resist film is formed thin nowadays for achieving the miniaturization of the semiconductor device. Therefore, the resist film tends to fail to perform sufficiently the function of the etching mask in etching a silicon oxide film so as to make it difficult to form a pattern with a high accuracy.

### BRIEF SUMMARY OF THE INVENTION

An object of the present invention is to provide an oxide film etching method capable of increasing the etching selectivity relative to the resist film in applying a dry etching treatment to an oxide film.

According to an aspect of the present invention, there is provided an etching method, in which a target object to be processed, which has an oxide film formed on the upper surface thereof, is held within a process chamber capable of maintaining a vacuum environment, and a plasma is generated in the etching gas atmosphere introduced into the process chamber so as to etch the oxide film formed on the target object within the plasma, wherein the etching gas contains C₄F₆ gas and O₂ gas, and the ratio C₄F₆/O₂ of the C₄F₆ gas to the O₂ gas falls within a range of 0.7 and 1.5.

On of the plasma generating mechanisms employed in the oxide film etching method of the present invention is of a RIE type in which a high frequency power for the plasma generation is applied to one of the electrodes that supports the target object, and the etching is performed under the conditions that the total flow rate of the C₄F₆ gas and the O₂ gas is set to fall within a range of 0.01 and 0.04 L/min, the ratio C₄F₆/O₂ of the C₄F₆ gas to the O₂ gas is set to fall within a range of 1.0 and 1.5, the gas pressure within the process chamber is set to fall within a range of 1.3 and 26 Pa (between 10 and 200 mTorr) in the etching step, and the plasma density is not lower than 3×10¹⁰/cm³ and lower than 1×10¹¹/cm³ in the etching step.

Also, another one of the plasma generating mechanism employed in the oxide film etching method of the present invention is of a capacity coupled parallel plate type in which different high frequency powers for plasma generation are applied to the electrodes, one of which supports the target object, and the etching is performed under the conditions that the total flow rate of the C₄F₆ gas and the O₂ gas is set to fall within a range of 0.03 and 0.1 L/min, the ratio C₄F₆/O₂ of the C₄F₆ gas to the O₂ gas is set to fall within a range of 0.7 and 1.1, the gas pressure within the process chamber is set to fall within a range of 1.33 and 9.97 Pa (between 10 and 75 mTorr) in the etching step, and the plasma density is not lower than 5×10¹⁰/cm³ and lower than 2×10¹¹/cm³ in the etching step.

Additional objects and advantages of the present invention will be set forth in the description which follows, and in part will be obvious from the description, or may be learned by practice of the present invention. The objects and advantages of the present invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the present invention, and together with the general description given above and the detailed description of the embodiments given below, serve to explain the principles of the present invention.

FIG. 1 shows as an example the construction of a magnetron RIE plasma etching apparatus used for working an oxide film etching method according to one embodiment of the present invention;

FIG. 2 schematically shows dipole ring magnets arranged around the process chamber included in the apparatus shown in FIG. 1;

FIG. 3 is for explaining the electric field and the magnetic field formed within the process chamber;

FIGS. 4A and 4B show the shoulder portion and the flat portion, respectively, of a resist mask for explaining the method for obtaining the etching selectivity;

FIGS. 5A and 5B are graphs each showing the relationship between the etching gas ratio C₄H₆/O₂ and the total flow rate of the etching gas (C₄H₆+O₂) in respect of the etching selectivity of the oxide film relative to the resist film;

FIGS. 6A and 6B are graphs each showing the relationship between the etching gas ratio C₅H₈/O₂ and the total flow rate of the etching gas (C₅H₈+O₂) in respect of the etching selectivity of the oxide film relative to the resist film;

FIG. 7 is a graph showing the relationship between the etching gas ratio C₄H₆/O₂ and the total flow rate of the etching gas (C₄H₆+O₂) in respect of the plasma density;

FIG. 8 is a graph showing the relationship between the gas pressure and the high frequency power in respect of the plasma density;

FIG. 9A is a graph showing the relationship between the high frequency power and the characteristics of the etching selectivity;

FIG. 9B is a graph showing the relationship between the gas pressure and the characteristics of the etching selectivity;

FIG. 10 shows as an example the construction of an etching apparatus used for working an oxide film etching method according to a second embodiment of the present invention, in which different high frequency powers are applied from the both electrodes;

FIG. 11 is a graph showing the relationship between the ratio C₄F₆/O₂ of the etching gas and the total flow rate of the C₄F₆ gas and the O₂ gas in respect of the etching selectivity relative to the resist film;

FIGS. 12A and 12B are cross sectional views collectively showing an example of applying the oxide film etching method of the present invention to the self-aligning etching using a silicon nitride film as a film provided beneath the oxide film; and

FIG. 13 is a graph showing the relationship between the ratio C₄F₆/O₂ of the etching gas and the total flow rate of the C₄F₆ gas and the O₂ gas in respect of the etching selectivity oxide film of the relative to the silicon nitride film.

### DETAILED DESCRIPTION OF THE INVENTION

The embodiments of the present invention will now be described with reference to the accompanying drawings.

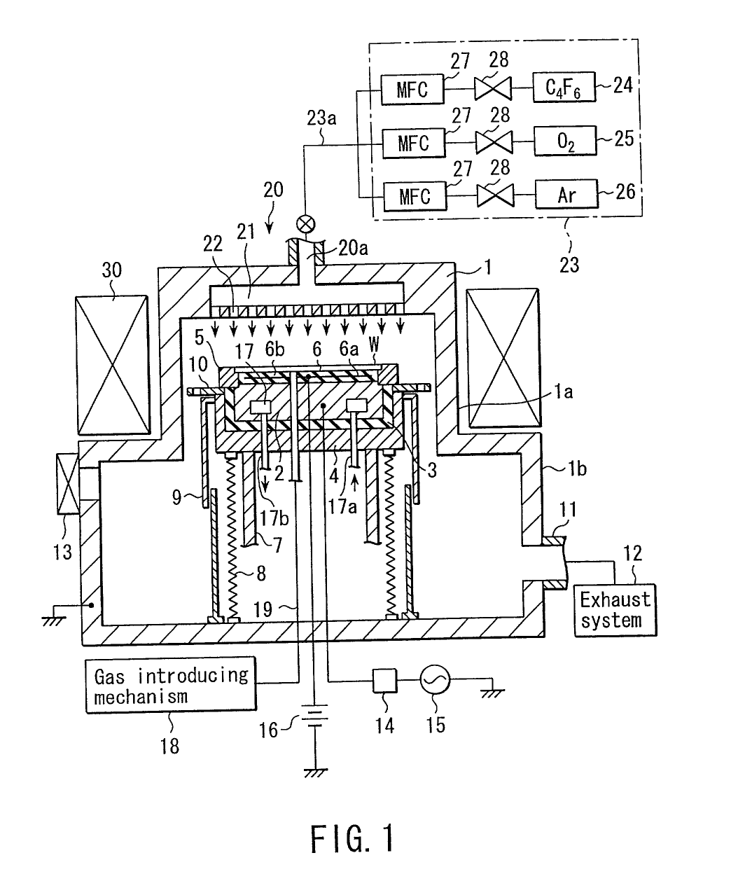

In the first embodiment of the present invention, a magnetron RIE (Reactive Ion Etching) plasma etching apparatus constructed as shown in FIG. 1 is used for working the oxide film etching method of the present invention.

As shown in FIG. 1, the etching apparatus comprises a stepped cylindrical process chamber 1 consisting of two cylinders differing from each other in diameter and connected to each other. Specifically, the process chamber 1 comprises an upper chamber 1a formed of aluminum and having a small diameter and a lower chamber 1b formed of aluminum and having a large diameter. These upper and lower chambers 1a and 1b are joined to each other to form the process chamber 1 capable of maintaining a vacuum environment. The process chamber 1 of the particular construction is grounded to bear a GND potential.

A susceptor for horizontally supporting a target object of a semiconductor wafer W is arranged within the process chamber 1. The susceptor comprises a support table 2 made of, for example, aluminum and a support base 4 made of a conductor and having the support table 2 fitted therein with an insulating plate 3 interposed therebetween.

The support table 2 is connected to a high frequency power source 15 for the plasma generation with a matching device 14 interposed therebetween. A high frequency power of a predetermined frequency, e.g., 13.56 MHz, is supplied from the high frequency power source 15 to the support table 2. Also, a focus ring 5 made of a conductive material such as a single crystalline silicon is arranged above the outer circumferential surface of the support table 2, and an electrostatic clampless holder 6 for electrostatically pulling and holding a semiconductor wafer W is arranged on the surface of the support table 2 inside the focus ring 5.

The electrostatic clampless holder 6 is formed by incorporating an electrode 6a within an insulating body 6b. A DC power source 16 is connected to the electrode 6a. If a voltage is applied from the DC power source 16 to the electrode 6a, an electrostatic force, e.g., a Coulomb force, is generated so as to attract the semiconductor wafer W. A coolant passage 17 is formed within the support table 2. A coolant from a cooling device (not shown) is circulated within the support table 2 such that the coolant is introduced into the coolant passage 17 through a coolant introducing pipe 17a and discharged from the coolant passage 17 through a coolant discharge pipe 17b. The semiconductor wafer W is cooled by the coolant through the support table 2 so as to control the treating surface of the wafer W at a desired temperature.

It should be noted that, as the interior of the process chamber 1 is placed in a vacuum environment, it is difficult to cool the semiconductor wafer W by the coolant. Therefore, a cooling gas is supplied from a gas introducing mechanism 18 into the clearance between the surface of the electrostatic clampless holder 6 and the back surface of the semiconductor wafer W through a gas supply line 19 so as to improve the cooling efficiency of the semiconductor wafer W.

A baffle plate 10 is arranged below the outer circumferential surface of the focus ring 5. The support table 2 and the support base 4 are made movable in the vertical direction by a ball screw mechanism including a ball screw 7, and the driving section below the support base 4 is covered with bellows 8 made of a stainless steel (SUS). The process chamber side put in a vacuum environment is separated from the ball screw mechanism side under the state of the atmospheric pressure by the bellows 8. Also, a bellows cover 9 is arranged on the side of the outer circumferential surface of the bellows 8. The focus ring 5 is electrically connected to the process chamber 1 through the baffle plate 10, the support base 4 and the bellow 8 so as to bear the GND potential.

An exhaust port 11 is formed in the side wall of the lower chamber 1b of the process chamber 1, and an exhaust system 12 is connected to the exhaust port 11. The process chamber 1 is evacuated to a predetermined degree of vacuum by operating a vacuum pump (not shown) of the exhaust system 12. On the other hand, an inlet/outlet port for transporting the semiconductor wafer W into and out of the process chamber 1 is formed in an upper portion of the side wall of the lower chamber 1b of the process chamber 1, and arranged is a gate valve 13 for opening/closing the inlet/outlet port from the outside.

A shower head 20 is arranged in the ceiling portion within the process chamber 1. A large number of gas blowout holes 22 are formed in the lower surface of the shower head 20, and the shower head 20 is arranged in parallel to the semiconductor wafer W held by the support table 2. Also, the shower head 20 has a GND potential, like the process chamber 1. A space 21 for diffusing the introduced gas is formed between the lower surface of the shower head 20 and a gas introducing portion 20a formed in an upper portion (ceiling portion within the process chamber 1).

One end of a gas supply pipe 23a is connected to the gas introducing portion 20a, and an etching gas supply system 23 for supplying an etching gas is connected to the other end of the gas supply pipe 23a. The etching gas supply system 23 includes, for example, a C₄F₆ gas source 24, an O₂ gas source 25, and an Ar gas source 26. A mass flow controller 27 and a valve 28 are mounted to each of the pipes connected to these etching gas sources.

The etching gases of the C₄F₆ gas, the O₂ gas and the Ar gas supplied from the gas supply sources are combined in the gas supply pipe 23a and introduced into the space 21 of the shower head 20 through the gas introducing portion 20a. Then, the combined gas is spurted from the gas blowout holes 22 into the process chamber 1 (process space) so as to form an etching gas atmosphere.

In the apparatus of the particular construction described above, the shower head 20 and the support table 2 facing the shower head 20 perform the functions of the upper electrode and the lower electrode, respectively. An etching gas atmosphere is formed in the process space between the shower head 20 and the support table 2, and a high frequency power is applied from the high frequency power source 15 to the support table 2 acting as the lower electrode so as to form a plasma.

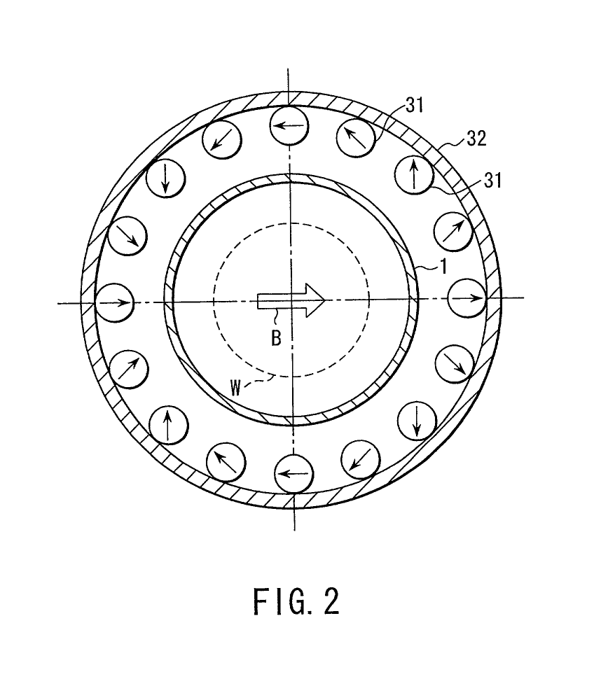

On the other hand, a dipole ring magnet 30 is arranged to surround the outer circumferential surface of the upper chamber 1a of the process chamber 1. FIG. 2 is a horizontal cross sectional view showing the dipole ring magnet 30. As shown in FIG. 2, a plurality of anisotropic segment columnar magnets 31 are mounted to the inner surface of an annular casing 32 made of a magnetic material so as to form the dipole ring magnet 30. In the example shown in FIG. 2, 16 anisotropic segment columnar magnets 31 are arranged to form a ring. The arrow in each of the anisotropic segment columnar magnets 31 denotes the direction of the magnetic flux. The plural anisotropic segment columnar magnets 31 are arranged such that the directions of the magnetic fluxes of the adjacent columnar magnets 31 are slightly deviated from each other so as to form as a whole a uniform horizontal magnetic field B extending in one direction.

If a high frequency power is applied from the high frequency power source 15 to the support table 2 acting as the lower electrode, a vertical electric field E is formed in the space between the support table 2 acting as the upper electrode and the shower head 20, as schematically shown in FIG. 3. In addition, the horizontal magnetic field B parallel to the surfaces of the upper and lower electrodes is formed by the dipole ring magnet 30. The magnetic field B thus formed is perpendicular to the electric field E formed between the upper and lower electrodes. A plasma (magnetron discharge) is generated in the electric field and the magnetic field thus formed, which are perpendicular to each other. If a plasma is generated in the etching gas atmosphere of a high energy state, the oxide film formed on the semiconductor wafer W is etched.

Let us describe the oxide film etching method of the present invention using the magnetron RIE plasma etching apparatus of the construction described above. In the following description, a silicon oxide film is used as an example of the oxide film.

In the first step, the gate valve 13 is opened so as to transfer the semiconductor wafer W into the process chamber 1 by using a wafer transfer mechanism (not shown) so as to permit the transferred semiconductor wafer W to be held by the support table 2. Then, the wafer transfer mechanism is retreated, followed by closing the gate valve 13. Further, the support table 2 is moved upward by the ball screw mechanism to the position shown in FIG. 2 and, at the same time, the process chamber 1 is evacuated by the vacuum pump included in the exhaust system 12 so as to set up a desired vacuum environment within the process chamber 1.

In the next step, a C₄F₆ gas and an O₂ gas are introduced as the etching gas from the etching gas supply system 23 into the process chamber 1. An Ar gas is also introduced into the process chamber 1, as required. The flow rates of the C₄F₆ gas and the O₂ gas are controlled by adjusting the mass flow controllers 27 such that the ratio C₄F₆/O₂ falls within a range of 0.7 and 1.5 so as to form an etching gas.

The gas pressure within the process chamber 1 is not particularly limited. However, according to experience, it is desirable for the gas pressure within the process chamber 1 to fall within a range of 1.3 and 26 Pa (between 10 and 200 mTorr). The flow rates of the C₄F₆ gas and the O₂ gas are not particularly limited either. However, it is desirable for the sum of the flow rates of the C₄F₆ gas and the O₂ gas to fall within a range of 0.01 and 0.04 L/min. Further, it is desirable for the Ar gas flow rate, which is not particularly limited, to fall within a range of 0 and 1 L/min. Incidentally, it is possible to use another inert gas in place of the Ar gas.

Under the state that the gaseous atmosphere noted above is set up within the process chamber 1, a predetermined high frequency power is applied from the high frequency power source 15 to the support table 2. In this step, a predetermined voltage is applied from the DC power source 16 to the electrode 6a of the electrostatic clampless holder 6 so as to permit the semiconductor wafer W to be electrostatically attracted to and supported by the electrostatic clampless holder 6. By the application of the high frequency power, a high frequency electric field is formed between the shower head 20 acting as the upper electrode and the support table 2 acting as the lower electrode. It should be noted that the horizontal magnetic field B is formed by the dipole magnet 30 between the shower head 20 and the support table 2 as described previously. It follows that an electromagnetic field in which the electric field and the magnetic field cross each other at right angles is formed in the process space between the upper and lower electrodes, in which the semiconductor wafer W is present. As a result, a magnetron discharge is generated by the drift of electrons generated in the process space. The oxide film on the semiconductor wafer W is etched by the plasma consisting of the magnetron discharge.

It is desirable for the plasma density in the etching step to be not lower than 3×10¹⁰/cm³ and lower than 1×10¹¹/cm³. If the plasma density is set to fall within the range noted above, it is possible to obtain a high etching selectivity. It is possible to set the plasma density at a desired value by controlling the high frequency power applied from the high frequency power source 15.

During the etching treatment, the temperature of the semiconductor wafer W is elevated by the function of the plasma. However, the semiconductor wafer W can be controlled at a desired temperature by the coolant circulated through the coolant passage 17. In general, a low wafer temperature is advantageous for obtaining a high etching selectivity relative to the resist film. However, a high wafer temperature is advantageous in some cases in terms of the etching characteristics of the oxide film such as the shape of the processing.

In the first embodiment of the present invention, it is possible to increase the etching selectivity of the oxide film relative to the resist film and, thus, it is desirable to set the wafer temperature during the etching treatment at 50° C. or more in terms of the improvement in, for example, the etching shape. More desirably, the wafer temperature should be set at 80° C. or more during the etching treatment.

The dipole ring magnet 30 serves to apply a magnetic field to the process space between the support table 2 forming the lower electrode and the shower head 20 forming the upper electrode in order to increase the plasma density above the semiconductor wafer W. In order to obtain the particular effect more prominently, it is desirable to use a strong magnet capable of forming a magnetic field of at least 3,000 μT (30 gauss) in the process space.

As described above, it is possible to increase the etching selectivity of the oxide film relative to the resist film by using, in the etching step, a mixed gas containing a C₄F₆ gas and an O₂ gas as an etching gas and by setting the ratio C₄F₆/O₂ of the C₄F₆ gas to the O₂ gas to fall within a range of 1.0 and 1.5. To be more specific, it is possible to increase the etching selectivity of the oxide film in the shoulder portion of a contact hole formed in the resist film to 5 or more, though the etching selectivity in this case was at most about 4 in the past.

It is possible to further increase the etching selectivity by setting the inner pressure of the process chamber, the flow rates of the C₄F₆ gas and the O₂ gas, the flow rate of the Ar gas, and the plasma density to fall within the desirable ranges described above.

Let us describe the experiments confirming that the etching method of the present invention produces prominent effects.

Specifically, a silicon oxide film formed on the surface of a semiconductor wafer W was etched by using a C₄F₆ gas, an O₂ gas and an Ar gas as the etching gas. In this experiment, the total flow rate of the C₄F₆ gas and the O₂ gas and the mixing ratio of the C₄F₆ gas to the O₂ gas were changed, with the Ar gas flow rate set constant at 0.5 L/min. In this case, the inner pressure of the process chamber was set at 5.32 Pa (40 mTorr). Also, a high frequency power of 1,500 W having a frequency of 13.56 MHz was applied to the susceptor and a magnetic field of 12,000 μT (120 gauss) was applied by the dipole ring magnet to the process space so as to form a plasma.

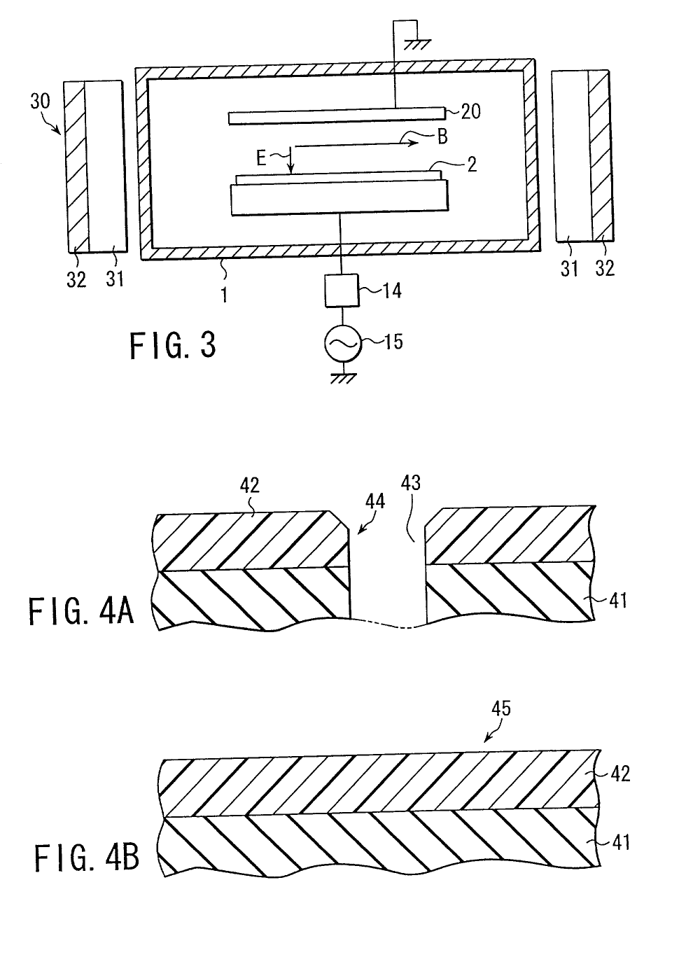

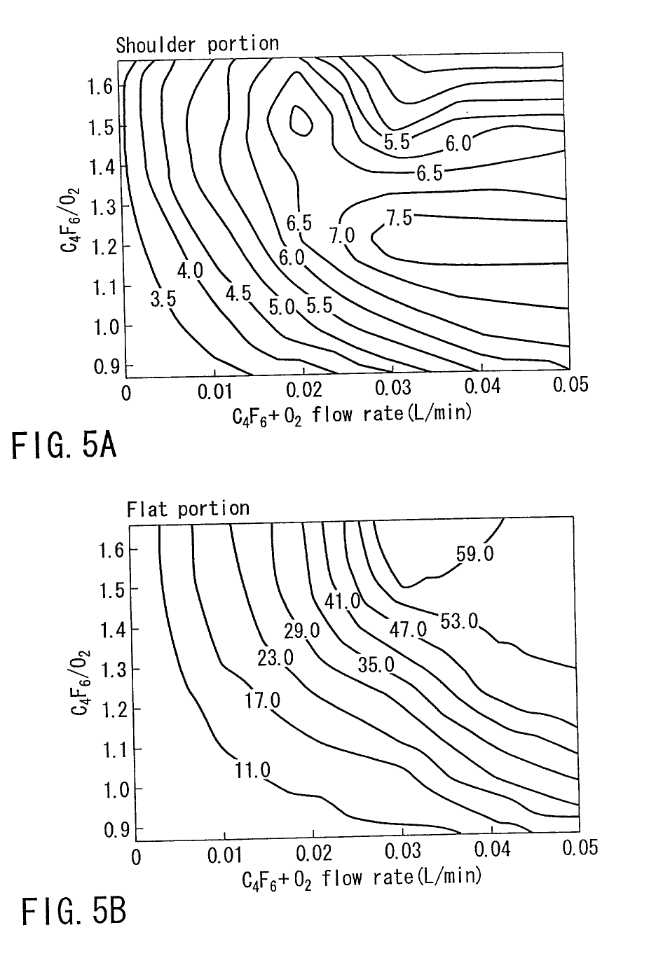

The etching selectivity of the silicon oxide film relative to the resist film was obtained by the etching process described above. The etching selectivity was obtained on the basis of the etching rate in a shoulder portion 44 of a contact hole 43 formed in a resist film 42 formed on a silicon oxide film 41 as shown in FIG. 4A and on the basis of the etching rate in a flat portion 45 of the resist film 42 as shown in FIG. 4B. The results are shown in the graphs of FIGS. 5A and 5B. In the graph of each of FIGS. 5A and 5B, the total flow rate of the C₄F₆ gas and the O₂ gas is plotted on the abscissa, with the ratio C₄F₆/O₂ of the C₄F₆ gas to the O₂ gas plotted on the ordinate, thereby showing the etching selectivity of the silicon oxide film relative to the resist film. FIG. 5A covers the etching selectivity on the basis of the shoulder portion of the resist film, with FIG. 5B covering the etching selectivity on the basis of the flat portion of the resist film.

As shown in FIG. 5A, it has been confirmed that, where the etching selectivity is measured on the basis of the shoulder portion where the resist film is most likely to be etched, it is possible to set the etching selectivity of the silicon oxide film relative to the resist film at about 5 or more in the case where the ratio C₄F₆/O₂ of the C₄F₆ gas to the O₂ gas is set to fall within a range of 1.0 and 1.5.

It has also been confirmed that a satisfactory etching selectivity can be obtained in the case where the total flow rate of the C₄F₆ gas and the O₂ gas is not lower than 0.01 L/min. However, if the total flow rate of the C₄F₆ gas and the O₂ gas exceeds 0.04 L/min, the deposition of the film was increased and the etching rate was lowered, although it was certainly possible to increase the etching selectivity. It follows that it is desirable for the total flow rate of the C₄F₆ gas and the O₂ gas to fall within a range of 0.01 and 0.04 L/min. It should be noted, however, that a suitable range of the gas flow rate somewhat differs depending on other conditions, such as the size of the process chamber.

As shown in FIG. 5B, it has also been confirmed that, where the etching selectivity is based on the flat portion of the resist film, a sufficiently high etching selectivity can be obtained in the case where the ratio C₄F₆/O₂ of the C₄F₆ gas to the O₂ gas falls within a range of 1.0 and 1.5.

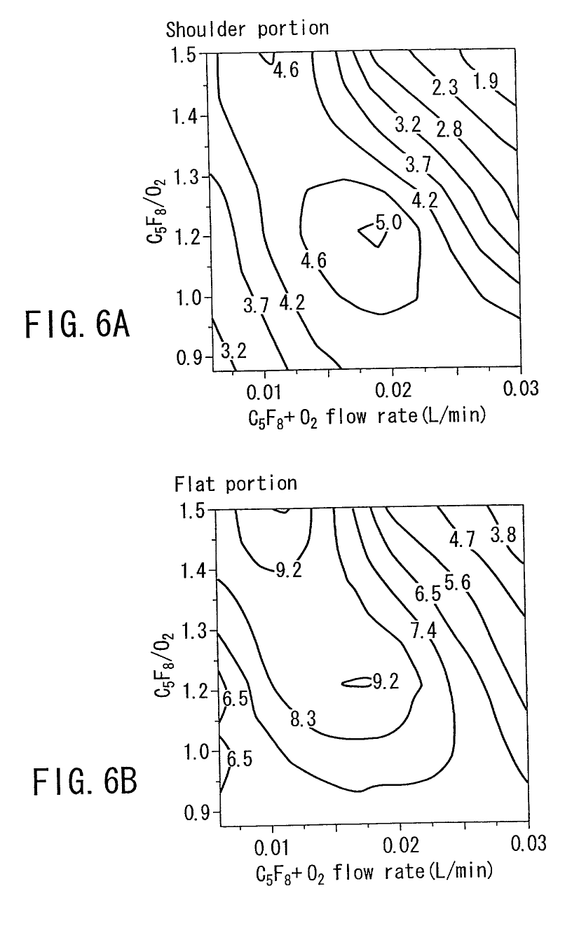

For comparison, an additional etching was performed under exactly the same conditions, except that a C₅F₈ gas was used in place of the C₄F₆ gas, so as to obtain the etching selectivity of the silicon oxide film in each of the shoulder portion and the flat portion of the resist film. FIGS. 6A and 6B are graphs showing the results. As apparent from the graphs, the etching selectivity of the silicon oxide film relative to the resist film was lower in the case of using the C₅F₈ gas than that in the case of using the C₄F₆ gas in each of the shoulder portion and the flat portion.

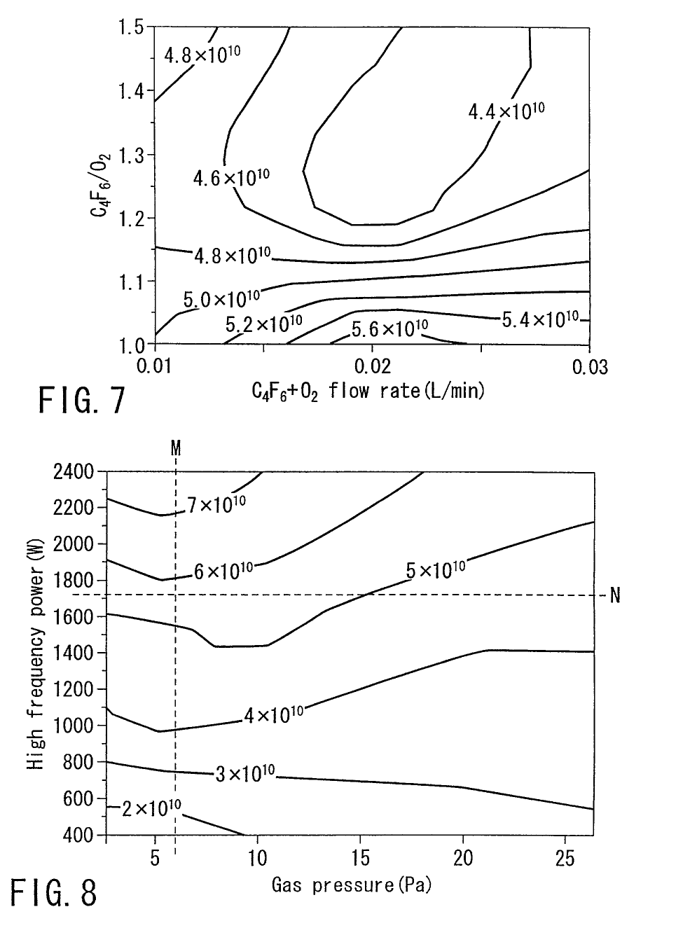

Then, an experiment to etch the silicon oxide film formed on the semiconductor wafer W was conducted by changing the total flow rate of the C₄F₆ gas and the O₂ gas and the mixing ratio of the C₄F₆ gas to the O₂ gas so as to obtain a plasma density. FIG. 7 is a graph showing the result. Specifically, FIG. 7 is a graph showing the relationship between the total flow rate of the C₄F₆ gas and the O₂ gas, which is plotted on the abscissa, and the ratio C₄F₆/O₂ of the C₄F₆ gas to the O₂ gas, which is plotted on the ordinate, in respect of the plasma density. As apparent from FIG. 7, the plasma density was on the order of 10¹⁰/cm³ in the range in which a good etching selectivity of the C₄F₆ gas and the O₂ gas can be obtained.

An additional etching test was conducted as above, except that the flow rates of the C₄F₆ gas, the O₂ gas and the Ar gas were set at 0.017 L/min, 0.013 L/min and 0.5 L/min, respectively, and the high frequency power and the gas pressure inside the process chamber were changed. FIG. 8 is a graph showing the plasma density during the test. Specifically, FIG. 8 is a graph showing the relationship between the gas pressure inside the process chamber, which is plotted on the abscissa, and the high frequency power, which is plotted on the ordinate, in respect of the plasma density. As apparent from FIG. 8, the plasma density is increased with increase in the high frequency power.

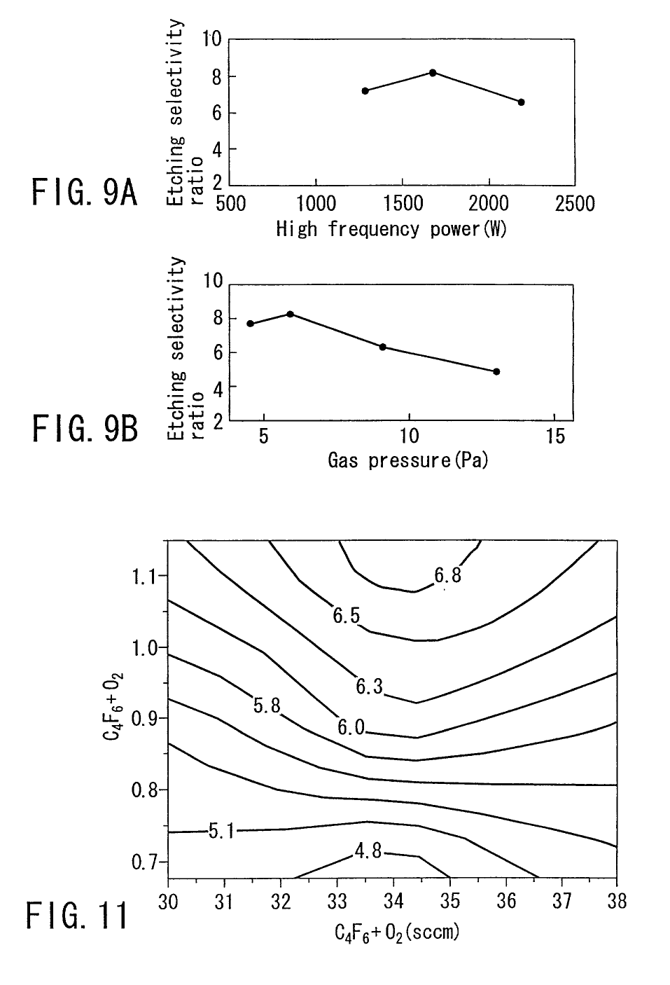

The etching selectivity of the silicon oxide film relative to the resist film in the shoulder portion was obtained in respect of lines M and N shown in FIG. 8. FIGS. 9A and 9B show the results. Specifically, FIG. 9A is a graph showing the relationship between the high frequency power and the etching selectivity, with the gas pressure set constant at 5.67 Pa. On the other hand, FIG. 9B is a graph showing the relationship between the gas pressure and the etching selectivity, with the high frequency power set constant at 1,700 W.

As shown in FIG. 9A, there is a phenomenon that the etching selectivity reaches a peak when the high frequency power is set at 1,700 W, and that the etching selectivity is lowered when the high frequency power is higher than 1,700 W.

If the phenomenon noted above is applied to the plasma density with reference to FIG. 8, the particular phenomenon implies that the etching selectivity is lowered if the plasma density exceeds about 5.5×10¹⁰/cm³. This clearly suggests that, in order to improve the etching selectivity, it suffices for the plasma density to be in the order of 1×10¹⁰/cm³. Also, FIG. 9B shows that the etching selectivity reached a peak when the gas pressure was set at 5.67 Pa.

The first embodiment of the present invention is not limited to the construction of the etching apparatus described previously, and can be modified in various fashions. For example, in the first embodiment, a dipole ring magnet was used as the means for forming a magnetic field in the etching apparatus. However, it is also possible to use another means for forming the magnetic field. Also, it is not absolutely necessary to form the magnetic field.

Also, the first embodiment of the present invention is applied to the magnetron RIE plasma etching apparatus. However, it is possible to apply the technical idea of the present invention regardless of the structure of the apparatus, as far as the requirement of the etching gas ratio is satisfied. Further, it is conceivable to apply the technical idea of the present invention to various plasma etching apparatuses of, for example, the capacity coupled.

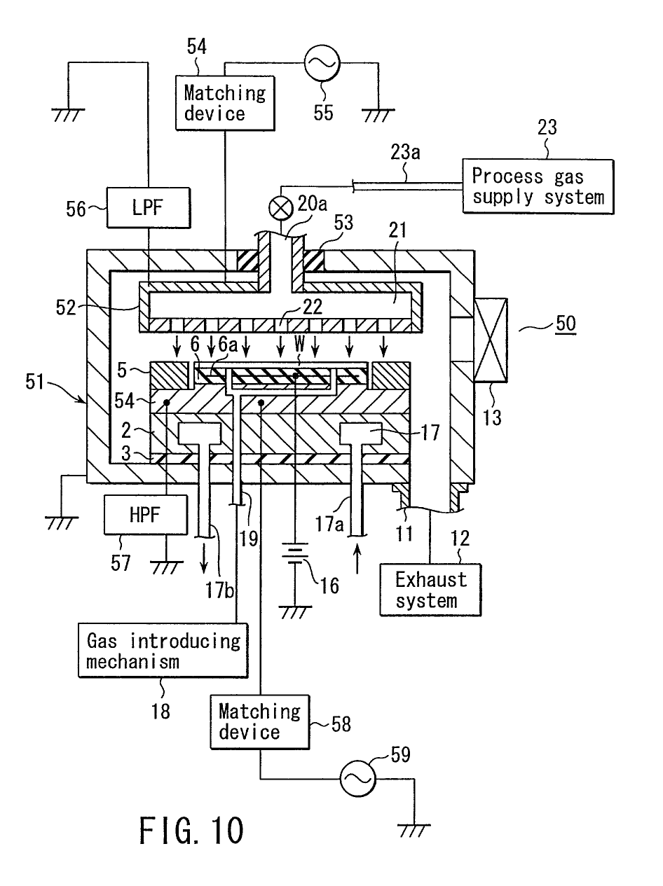

FIG. 10 shows the construction of a capacity coupled type parallel plate etching apparatus 50 according to a second embodiment of the present invention. The elements of the etching apparatus 50 shown in FIG. 10 equal to that of the first embodiment shown in FIG. 1 described previously are denoted by the same reference numerals so as to avoid an overlapping description.

The etching apparatus 50 shown in FIG. 10 has a cylindrical process chamber 51 made of, for example, an anodized aluminum having a surface subjected to an anodic oxidation treatment. The process chamber 51 is electrically connected to the ground so as to bear the GND potential.

A susceptor holding a semiconductor wafer W and acting as a lower electrode is arranged in a bottom portion of the process chamber 51. A support table 2 is arranged on the bottom of the process chamber 51 with an insulating plate 3 such as a ceramic plate interposed therebetween. A susceptor section 54 acting as a lower electrode and having the semiconductor wafer W disposed thereon is formed on the support table 2, and a high pass filter (HPF) 57 is connected to the susceptor section 54.

The susceptor section 54 is formed in the shape of a disk having a projecting portion formed in the central portion on the upper surface, and an electrostatic clampless holder 6 substantially equal in shape to the semiconductor wafer W is mounted to the projecting portion of the susceptor section 54. The electrostatic clampless holder 6 comprises an insulating body 6b and an electrode 6a incorporated in the insulating body 6b, and a DC power source 16 is connected to the electrode 6a. A voltage of about 1.5 kV is applied from the DC power source 16 to the electrode 6a so as to permit the electrostatic clampless holder 6 to electrostatically attract the semiconductor wafer W. In other words, the semiconductor wafer W is attracted to the electrostatic clampless holder 6 by the Coulomb force. A coolant passage 17 is formed within the support table 2. A coolant is introduced into the coolant passage 17 from a cooling apparatus (not shown) through a coolant introducing pipe 17a and is discharged from within the coolant passage 17 through a coolant discharge pipe 17b. The semiconductor wafer W is cooled by the coolant through the support table 2 so as to control the wafer treating surface at a desired temperature.

Where a vacuum environment is established within the process chamber 1, the semiconductor wafer W is unlikely to be cooled by the coolant within the coolant passage 17. Therefore, a gas supply line 19 is formed to extend through the insulating plate 3, the support table 2, the susceptor section 54 and the electrostatic clampless holder 6 so as to reach the back surface of the semiconductor wafer W. The gas supply line 19 thus formed is connected to a gas introducing mechanism 18. By this construction, a cooling gas is supplied from the gas introducing mechanism 18 into the clearance between the upper surface of the electrostatic clampless holder 6 and the back surface of the semiconductor wafer W through the gas supply line 19 so as to enhance the cooling effect.

An annular focus ring 5 made of a conductive material such as silicon is formed in the upper circumferential surface of the susceptor section 54 in a manner to surround the semiconductor wafer W held on the electrostatic clampless holder 6. The focus ring 5 thus formed serves to improve the uniformity of the etching.

An upper electrode 52 that also performs the function of a shower head is arranged above the susceptor performing the function of the lower electrode such that the upper electrode 52 extends in parallel to the semiconductor wafer W held by the susceptor. The upper electrode 52 is supported in the ceiling portion of the chamber 51 via an insulating member 53. The upper electrode 52 is formed in the shape of a box and comprises a lower portion facing the susceptor and a support portion supporting the lower portion and positioned on the side of the ceiling. The lower portion and the support portion are spaced apart defining a space 21 between them.

The lower surface portion of the upper electrode 52, in which a large number of blowout holes 22 are formed, is formed of, for example, silicon, silicon carbide (SiC) or an amorphous carbon. Further, the supporting portion is formed of a conductive material such as anodized aluminum having the surface subjected to the anodizing treatment. Incidentally, the positions of the upper electrode 52 and the susceptor are adjusted to provide a clearance (treating space) of about, for example, 10 to 60 mm between the semiconductor wafer W and the upper electrode 52.

A gas introducing port 20a is arranged in the central portion in the supporting portion of the upper electrode 21. Also, the gas introducing port 20a is connected to one end of a gas supply pipe 23a having a valve mounted thereto. The other end of the gas supply pipe 23a is connected to a process gas supply source 23. The process gas supply source 23 is provided with a plurality of gas sources, valves mounted to the gas sources and mass flow controllers connected to the gas sources as in the first embodiment shown in FIG. 1. The etching gas similar to that used in the first embodiment described previously is supplied from the process gas supply source 23 into the process chamber 51.

An exhaust pipe 11 and an exhaust system 12 are connected to the bottom portion of the process chamber 51 so as to exhaust the inner space of the process chamber 51, thereby setting up a vacuum environment having a pressure not higher than, for example, 1 Pa within the process chamber. Also, a gate valve 13 equal to that used in the first embodiment is formed in the side wall of the process chamber 51.

Further, a first high frequency power source 55 generating a high frequency power is connected to the upper electrode 52 via a matching device 54. A low pass filter (LPF) 56 is also connected to the upper electrode 52. The first high frequency power source 55 supplies a high frequency power to the upper electrode 52 so as to form a plasma of a high density in a desired dissociated state in the process space of the process chamber 51. As a result, the plasma processing can be performed under a lower pressure condition than in the prior art. It is desirable for the output frequency of the first high frequency power source 55 to fall within a range of 50 and 80 MHz, preferably about 60 MHz.

A second high frequency power source 59 is connected to the susceptor 54 acting as the lower electrode via a matching device 58. It is desirable for the output frequency of the second high frequency power source 59 to fall within a range of 1 and 4 MHz, preferably about 2 MHz. In this case, an appropriate ionic function can be imparted by the high frequency power generated from the second high frequency power source 59 without damaging the semiconductor wafer W.

Let us describe the etching of a silicon oxide film by the oxide film etching method of the present invention using the capacity coupled type parallel plate etching apparatus of the construction described above.

In the first step, a semiconductor wafer W having a silicon oxide film formed thereon is introduced into the process chamber through the gate valve so as to dispose the semiconductor wafer W on the electrostatic clampless holder. Then, the inner space of the process chamber is evacuated by the exhaust system to a predetermined vacuum state, followed by introducing the etching gas equal to that in the first embodiment described previously from the process gas supply source 30 into the process chamber so as to spurt the etching gas uniformly onto the semiconductor wafer W.

Under the condition described above, a high frequency power of, for example, 60 MHz is applied from the first high frequency power source to the upper electrode while maintaining the pressure within the chamber 51 at a predetermined level. By this application of the high frequency power, a high frequency electric field is generated in the space between the upper electrode and the susceptor acting as the lower electrode. As a result, the etching gas is dissociated so as to generate a plasma.

A high frequency power of, for example, 2 MHz is applied from the second high frequency power source 59 to the lower electrode. By this application of the high frequency power, the ions within the plasma are attracted toward the susceptor so as to enhance the anisotropy of the etching by the ion assist.

An etching similar to that in the first embodiment was also performed in the second embodiment of the present invention. FIG. 11 is a graph showing the relationship between the total flow rate of the C₄F₆ gas and the O₂ gas, which is plotted on the abscissa, and the ratio C₄F₆/O₂ of the C₄F₆ gas to the O₂ gas, which is plotted on the ordinate, in respect of the etching selectivity relative to the resist film. As apparent from FIG. 11, it has been confirmed that it is possible to achieve at least 4.6 and substantially 6 or more of the etching selectivity of the silicon oxide film relative to the resist film.

Concerning the etching conditions for obtaining the data of the etching selectivity, the ratio C₄F₆/O₂ of the C₄F₆ gas to the O₂ gas, which were used as the etching gas, was set to fall within a range of 0.7 and 1.1. Also, the total flow rate of the C₄F₆ gas and the O₂ gas was set to fall within a range of 0.03 and 0.1 L/min. The pressure of the gas atmosphere within the etching apparatus was set at 3.99 Pa (30 mTorr), which was selected from the range of 1.33 and 9.97 Pa (between 10 and 75 mTorr). The plasma density was set to fall within a range of 5×10¹⁰ and 2×10¹¹/cm³. The wafer temperature was set at a level not lower than 100° C. Further, a high frequency power of, for example, 1,530 W (60 MHz) was applied to the upper electrode, and a high frequency power of, for example, 1,350 W (2 MHz) was applied to the lower electrode so as to generate a plasma.

Argon (Ar), which is an inert gas, is mixed with the etching as at a constant rate of 0.8 L/min.

As described above, in the second embodiment of the present invention, the ratio C₄F₆/O₂ of the C₄F₆ gas to the O₂ gas used as the etching gas was set to fall within a range of 0.7 and 1.1 in etching the oxide film, thereby markedly improving the etching selectivity of the oxide film relative to the resist film, compared with the prior art.

In each of the first and second embodiments of the present invention described above, an Ar gas was used in addition to the C₄F₆ gas and the O₂ gas. However, it is also possible to use another inert gas in place of the Ar gas. Further, each of the first and second embodiments described above is directed to the etching of a silicon oxide film. However, the particular etching method of the present invention can also be applied to another oxide film such as a film having a low dielectric constant.

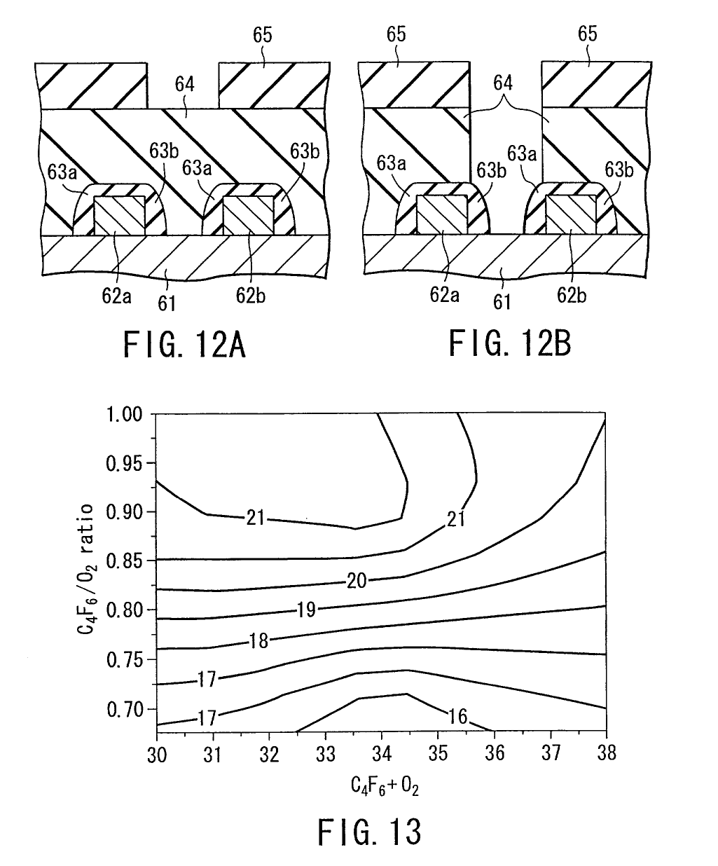

For example, the etching method of the present invention can also be applied to the self-aligning etching using a silicon nitride film as a film provided beneath the oxide film. Specifically, the etching method of the present invention can also be applied to the self-aligning contact etching in the case where a contact is formed in the channel region, into which an impurity has been diffused, between the circuit elements (dual gates) as shown in, for example, FIGS. 12A and 12B.

For forming the laminate structure shown in the drawing, two gate electrodes 62a, 62b are formed on a semiconductor wafer 61, followed by forming side walls 63a, 63b consisting of a nitride film, e.g., a silicon nitride (SiN) film, on both sides of each of these gates 62a, 62b. Further, after deposition of an interlayer insulating film 64 consisting of, for example, a silicon oxide film, formed is a mask pattern 65 consisting of a thin resist film.

Etching is applied to the laminate structure of the particular construction by using a capacity coupled type parallel plate etching apparatus as described in conjunction with the second embodiment of the present invention so as to etch the silicon oxide film. The silicon oxide film is etched in a manner to form a contact hole in the interlayer insulating film 64. In this case, where the side wall consisting of the silicon nitride film is exposed to the outside, the etching is performed in a self-aligned fashion with the exposed portion acting as a mask, thereby exposing the surface of the semiconductor wafer to the outside. If the silicon oxide film has lower selectivity than the silicon nitride film, the silicon nitride film will be etched. In this case, the silicon oxide film cannot be shaped as described.

FIG. 13 is a graph showing the relationship between the total flow rate of the C₄F₆ gas and the O₂ gas, which is plotted on the abscissa, and the ratio C₄F₆/O₂ of the C₄F₆ gas to the O₂ gas, which is plotted on the ordinate, in respect of the etching selectivity of the oxide film relative to the silicon nitride film. The etching conditions for obtaining the particular relationship were equal to the etching conditions for the second embodiment described previously.

As described above, it has been confirmed that it is possible to obtain an etching selectivity of at least 15 of the silicon oxide film relative to the silicon nitride film.

In each of the first and second embodiments of the present invention described above, the appropriate range of the total flow rate of the C₄F₆ gas and the O₂ gas slightly differs depending on the other conditions such as the size of the process chamber. Therefore, in the oxide film etching method of the present invention, it is possible to standardize the etching method to some extent by defining that the etching gas is in the state of contributing to the etching function. Specifically, the state that the etching gas contributes to the etching function denotes the state that the etching gas resides on the semiconductor wafer. Actually, the etching gas is supplied in a manner to flow from above the semiconductor wafer toward the outer circumferential side because the etching gas is discharged from the process chamber after the etching operation. Therefore, the time during which the etching gas flows over the semiconductor wafer W is defined as the residence time τ.

The residence time τ is proportional to the volume V(L) defined by the area of the semiconductor wafer W and the gap between the upper and lower electrodes and is inversely proportional to the discharge rate S (L/sec) achieved by the discharge system. In other words, the residence time τ is equal to the value obtained by dividing the product between the volume V and the pressure p (degree of vacuum: Torr) at that time by the total flow rate Q (sccm) as given below:

τ=V/S=pV/Q

For example, the residence time τ is 1.24 msec in the case where the semiconductor wafer has a diameter of 200 mm and the gap between the upper and lower electrodes is 27 mm (volume V in this case being 0.85 L), the pressure is 10 mTorr, and the total gas flow rate Q is 540 sccm (C₄F₆/Ar/O₂=23/500/17, where 1 Torr·L/sec=79.05 sccm).

The minimum residence time and the maximum residence time for each of the first and second embodiments of the present invention are as follows, if calculated by the method described above.

<First Embodiment>

| | |
|---|---|
| Diameter of semiconductor wafer: | 200 mm |
| Distance between electrodes: | 27 mm |
| Total gas flow rate Q: | 510 to 540 sccm |
| Chamber pressure p: | 10 to 200 mTorr |

(a) The residence time τ is 1.24 msec in the case where the total gas flow rate Q is 540 sccm and the chamber pressure p is 10 mTorr.

(b) The residence time τ is 26.3 msec in the case where the total gas flow rate Q is 510 sccm and the chamber pressure p is 200 mTorr.

<Second Embodiment>

| | |
|---|---|
| Diameter of semiconductor wafer: | 200 mm |
| Distance between electrodes: | 25 mm |
| Total gas flow rate Q: | 830 to 900 sccm |
| Chamber pressure p: | 10 to 75 mTorr |

(a) The residence time τ is 0.69 msec in the case where the total gas flow rate Q is 900 sccm and the chamber pressure p is 10 mTorr.

(b) The residence time τ is 5.6 msec in the case where the total gas flow rate Q is 830 sccm and the chamber pressure p is 75 mTorr.

Incidentally, the gap between the upper electrode and the lower electrode is not fixed but is variable so as to control the uniformity of the etching. In each of the first and second embodiments of the present invention, the gap noted above can be controlled within a range of 20 mm and 50 mm.

The use of the residence time based on the size of the semiconductor wafer is an important factor in comparing the etching apparatus or in determining the etching conditions even in the case where the inner volume of the process chamber and the discharge rate are different.

As described above, in the oxide film etching method of the present invention, the ratio C₄F₆/O₂ of the C₄F₆ gas to the O₂ gas used as the etching gas is set to fall within a range of 0.7 and 1.5 so as to markedly improve the etching selectivity of the oxide film relative to the resist film, compared with the prior art.

Note that C₄F₆ may be one having a ring structure, not the above-mentioned one having a straight chain structure.

The method of etching an oxide film, according to the invention, can be applied not only to magnetron RIE type plasma etching and capacity coupled type plasma etching, but also to induction coupling type plasma etching and the like. The method increases the etching selectivity that the oxide film exhibits to the resist. Hence, the thin resist mask may work as an etching mask that achieves high-resolution etching.

Also, the oxide film etching method of the present invention can be easily applied to, for example, an induction coupling type plasma etching as well as to the magnetron RIE type plasma etching and the capacitance coupling type plasma etching so as to improve the etching selectivity of the oxide film relative to the resist film. As a result, a thin resist mask is allowed to perform sufficiently the function of an etching mask while conforming with a high resolution.

Additional advantages and modifications will readily occur to those skilled in the art. Therefore, the present invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An etching method, in which a target object to be processed, which has an oxide film formed on the upper surface thereof, is held within a process chamber capable of maintaining a vacuum environment, and a plasma is generated in the etching gas atmosphere introduced into said process chamber so as to etch said oxide film formed on said target object within the plasma, wherein said etching gas including a C₄F₆ gas and an O₂ gas, and a ratio C₄F₆/O₂ of the C₄F₆ gas to the O₂ gas falls within a range of 0.7 and 1.5.

2. The oxide film etching method according to claim 1, wherein said etching gas further contains an inert gas in addition to said C₄F₆ gas and said O₂ gas.

3. The oxide film etching method according to claim 1, wherein the gas pressure within said process chamber is set to fall within a range of 1.3 and 26 Pa (between 10 and 200 mTorr) in the etching step.

4. The method according to claim 1, wherein the total flow rate of the C₄F₆ gas and the O₂ gas into said process chamber is set to fall within a range of 0.01 and 0.1 L/min in the etching step.

5. The method according to claim 1, wherein the residence time of C₄F₆ and O₂ ranges from 0.69 msec to 26.3 msec.

6. The method according to claim 1, wherein the plasma density in the etching step is not lower than 3×10¹⁰/cm³ and is lower than 2×10¹¹/cm³.

7. The method according to claim 1, wherein the temperature of said target object is set at 50° C. or higher in the etching step.

8. The method according to claim 1, wherein the silicon nitride film is exposed when the silicon oxide film is etched.

9. The method according to claim 8, wherein the silicon oxide film is etched in a self-alignment contact process.

10. The method according to claim 1, wherein said mechanism for generating a plasma is of a capacity coupled etching type, in which a high frequency electric field is formed between a pair of mutually facing electrodes for generating a plasma.

11. The method according to claim 8, wherein said mechanism for generating a plasma is of a RIE (Reactive Ion Etching) type, in which a high frequency power for generating a plasma is applied to one electrode holding said target object.

12. The method according to claim 10, wherein said mechanism for generating a plasma is of a type, in which different high frequency powers for generating a plasma are applied to both of said electrodes.

13. The method according to claim 11, wherein the etching is performed a magnetic field perpendicular to the electric field in the space between said electrodes.

14. The method according to claim 10, wherein said magnetic field is formed by magnetic field forming means having a dipole ring magnetic in which a plurality of anisotropic segment magnets are arranged to form a ring such that the directions of the magnetization of said anisotropic segment magnets are controlled to form a uniform magnetic field of one direction between the pair of electrodes.

15. The method according to claim 9, wherein the etching selectivity of the oxide film relative to the shoulder portion of the mask pattern formed of a resist film is at least 5.

16. A method of etching an oxide film, which uses a RIE (Reactive Ion Etching) mechanism in which a process chamber can maintain a vacuum, a high-frequency electric filed is generated between a pair of opposing electrodes and high-frequency power is supplied to one of the electrodes, which holds an object, and in which the object with the oxide film formed on an upper surface is held, a plasma is generated in an atmosphere of an etching gas introduced into the process chamber, the oxide film formed on the object is etched in the plasma, and RIE is performed in the following conditions:
C₄F₆ and O₂ are applied at a total flow rate of 0.01 to 0.04 L/min;
C₄F₆ is applied in a ratio of 1.0 to 1.5 with respect to O₂;
a gas pressure of 1.3 to 26 Pa (10 to 200 mTorr) is maintained in the process chamber ranges during the etching; and
the plasma has a density of at least 3×10¹⁰/cm³, not exceeding 1×10¹¹/cm³, during the etching.

17. A method of etching an oxide film, which uses a mechanism in which a high frequency electric filed is applied between opposing two electrodes provided in a process chamber maintained in a vacuum, thereby to supply high frequency power to both electrodes to generate a plasma, a high-frequency electric filed is generated between a pair of opposing electrodes and high-frequency power is supplied to both electrodes an object, and in which the object with the oxide film formed on an upper surface is held, a plasma is generated in an atmosphere of an etching gas introduced into the process chamber, the oxide film formed on the object is etched in the plasma, and RIE is performed in the following conditions:
C₄F₆ and O₂ are applied at a total flow rate of 0.03 to 0.1 L/min;
C₄F₆ is applied in a ratio of 0.7 to 1.1 with respect to O₂;
a gas pressure of 1.33 to 9.97 Pa (10 to 75 mTorr) is maintained in the process chamber ranges during the etching; and
the plasma has a density of at least 5×10¹⁰/cm³, not exceeding 2×10¹¹/cm³, during the etching.
